(19) United States
(12) Patent Application Publication
(10) Pub. No.: US 2011/0001191 A1
(43) Pub. Date: Jan. 6, 2011

(54) SEMICONDUCTOR DEVICE AND METHOD FOR MANUFACTURING THE SAME

(75) Inventors: Akio SHIMA, Hino (JP); Nobuyuki SUGII, Tokyo (JP)

Correspondence Address: MILES & STOCKBRIDGE PC, 1751 PINNACLE DRIVE, SUITE 500, MCLEAN, VA, 22102-3833, US

(73) Assignee: HITACHI, LTD.

(21) Appl. No.: 12/830,379

(22) Filed: Jul. 5, 2010

(30) Foreign Application Priority Data
Jul. 6, 2009 (JP) 2009-159412

(51) Int. Cl. H01L 29/786; H01L 21/84

(52) U.S. Cl. 257/347; 438/151; 257/E21.704; 257/E29.285

(57) ABSTRACT

A semiconductor device which includes: a semiconductor layer formed over an insulating layer over a semiconductor substrate; a gate electrode disposed over the semiconductor layer through a gate insulator; a sidewall insulator formed along the gate insulating film and a sidewall of the gate electrode; a source/drain layer including an alloy layer whose bottom surface is in contact with the insulating layer; and an impurity-doped layer which is segregated in a self-aligned manner in an interface between the alloy layer and the semiconductor layer and has a face for junction with a channel region formed along a crystal orientation plane of the semiconductor layer.

### CLAIM OF PRIORITY

The present application claims priority from Japanese patent application JP 2009-159412 filed on Jul. 6, 2009, the content of which is hereby incorporated by reference into this application.

### FIELD OF THE INVENTION

The present invention relates to semiconductor devices and a method for manufacturing the same and more particularly to technology which is useful for a MIS (Metal Insulator Semiconductor) transistor formed on an SOI wafer.

### BACKGROUND OF THE INVENTION

As for large-scale integrated circuits (LSIs) used in microcomputers for digital appliances and personal computers, there has been demand for higher speed, lower power consumption, and multifunctionality. In electronic devices as circuit components, for example, MIS transistors as typified by silicon (Si) field-effect transistors (FETs), device performance improvements (increase in current driving force and reduction in power consumption) have been so far achieved mainly by shortening the gate length using a lithographic technique. However, in MIS transistors with a gate length of 100 nm or less, it is difficult to achieve both performance improvement and reduction in power consumption only by such microfabrication technology because a short channel effect may cause saturation (or decrease) of the performance improvement rate and an increase in power consumption.

In addition to these problems, a new problem that device-to-device performance variation arises with the progress in microfabrication technology is becoming more serious. As device-to-device performance variation becomes larger, it becomes difficult to achieve reduction in supply voltage which has been pursued with the introduction of microfabrication technology in order to get the voltage margin required to assure normal operation of all circuits.

This also makes it difficult to decrease power consumption per device, resulting in an increase in power consumption of a semiconductor chip whose degree of integration has been increased with microfabrication. Furthermore, if device-to-device performance variation is large, a device with poor power consumption performance could seriously increase power consumption of the entire chip. As a consequence, it is now difficult to increase the circuit scale and functionality of a chip with the same area through a microfabrication process without causing change in its power consumption, though that was possible in the past.

JP-A-2005-251776 discloses a silicon-on-insulator (SOI) technique as a technique which can drastically improve the semiconductor chip performance by suppression of device-to-device performance variation. Unlike former SOI techniques, this technique uses an SOI substrate having a very thin SOI layer and a very thin buried oxide (BOX) layer to form a fully-depleted silicon-on-insulator (FDSOI) device and makes it possible to change the threshold voltage of the device by application of bias voltage to the back of the BOX layer.

The use of a thin SOI layer leads to a shallow source/drain semiconductor region for a MIS transistor. Also, in making a source/drain semiconductor region for a MIS transistor using a bulk Si wafer, the impurity concentration profile concerning a source/drain extension and a halo structure is designed to reduce the short channel effect by formation of a shallow source/drain semiconductor region. The formation of such a shallow source/region semiconductor region is useful in reducing the influence of an electric field on the channel region and suppressing a punch-through phenomenon. However, since this causes an increase in the source/drain parasitic resistance, a raised Si layer is formed only in the source/drain region by selective epitaxial growth as illustrated in FIG. 1 to decrease the source/drain parasitic resistance. Techniques of this kind are disclosed in JP-A-Hei8(1996)-298328, JP-A-2001-15745, and JP-A-Hei11(1999)-74506.

These patent documents describe the use of a facet which is formed through selective epitaxial growth so that the gate side end surface of the raised Si layer is inclined.

However, the formation of an raised Si layer by selective epitaxial growth requires a processing temperature of 800° C. or more, which may cause the following problems: a problem that the impurity concentration profile concerning an extension structure formed before selective epitaxial growth may deviate from the design profile and a problem that unless the facet formed according to the selective epitaxial growth conditions for a raised layer is precisely controlled, fluctuations may occur in subsequent processes, resulting in a failure to achieve the objective of reducing the device-to-device performance variation even when an SOI substrate is used.

Another approach is to use metal silicidation (alloying) of the surface of the source/drain layer in order to prevent the source/drain layer of a miniaturized field-effect transistor from having a high resistance. For example, JP-A-2002-110991 discloses a technique that the junction interface between the silicon diffusion layer and metal silicide layer in an SOI layer is formed as a (111) silicon plane for the purpose of reducing junction leaks in the metal silicide layer.

Recently, Schottky barrier MIS transistors which have a source/drain layer of metal silicide have been attracting attention as devices which demonstrate good short-channel characteristics.

FIG. 2 shows an example of the structure of a Schottky barrier MIS transistor. A MIS transistor which adopts Schottky tunnel junction is formed on an SOI substrate. A gate electrode is located over the channel region of the silicon layer with a gate insulator between the electrode and the channel region and a metal silicide source region and a metal silicide drain region are located on both sides of the channel region.

How the Schottky barrier MIS transistor operates is explained below referring to the energy band chart of FIG. 3. The explanation is given by taking a p-type MIS transistor as an example. When a gate voltage is applied, the tunnel resistance decreases and currents flow more easily. However, the meta/Si Schottky junction at the source/drain terminal may become a resistance component and generate an interface contact resistance, thereby suppressing the on current of the transistor. Although low-resistance silicides such as titanium silicide (TiSi₂), cobalt silicide (CoSi₂), and nickel monosilicide (NiSi) have been considered as possible metal materials for source and drain regions, in case of using these materials, the electronic barrier in an n-type MIS transistor and the hole barrier in a p-type MIS transistor are relatively high at 0.6 eV. Although a high barrier in a Schottky barrier MIS transistor is advantageous in suppressing the off current, it is disadvantageous in increasing the on current.

If a low-resistance silicide such as titanium silicide (TiSi₂), cobalt silicide (CoSi₂), or nickel monosilicide (NiSi) is used to form a silicide layer, lateral silicide reaction quickly proceeds in the silicide layer thus formed as a face-centered orthorhombic crystal, so in case of a MIS transistor with a very small gate length, for example, 500 nm or less (semiconductor channel region), the whole Si channel region is occupied by silicide as illustrated in FIG. 4, causing the transistor to fail to function as a transistor.

As a solution to this problem, JP-A-2006-344804 discloses a method in which a source and a drain are made of nickel disilicide. According to a known disilicide formation method, nickel disilicide can be formed only by lamp annealing for a time duration of several seconds at 850° C. or higher temperature. Disilicide, which is formed as a face-centered cubic lattice structure, includes not only normal (100) planes but also many (111) facets. Therefore, as illustrated in FIG. 5, in the Si channel region, a metal layer, constituting a source/drain layer, extends in the depth direction. Therefore, the Schottky barrier in a deep area of the channel which is less influenced by a gate voltage applied from the gate electrode is higher, which is undesirable in terms of transistor characteristics. Furthermore, JP-A-2006-344804 describes that after formation of a silicide layer by nickel sputter deposition and annealing, impurities are segregated by impurity ion implantation and low-temperature lamp annealing to decrease the interface contact resistance. This technique has a problem that although dopant segregation occurs, the activation ratio of the segregated impurity layer is low due to low-temperature annealing, namely the interface contact resistance remains high, so the effect of decreasing the metal/Si Schottky barrier is low.

### SUMMARY OF THE INVENTION

An object of the present invention is to provide a semiconductor device in which a raised source/drain structure is formed in the thin film semiconductor layer of an FDSOI MIS transistor as typified by an ultra-ultra-thin SOI layer without selective Si epitaxial growth, and a method for manufacturing the same. Another object of the invention is to provide a semiconductor device in which junction leaks are suppressed and the resistance of the source/drain layer is decreased with reduction in the short-channel effect, and a method for manufacturing the same. A further object of the invention is to provide a semiconductor device in which the tunnel resistance and drain terminal resistance in a Schottky barrier MIS transistor during operation of the transistor can be reduced, and a method for manufacturing the same.

The above and further objects and novel features of the invention will more fully appear from the following detailed description in this specification and the accompanying drawings.

Typical aspects of the invention which are disclosed herein are briefly summarized below.

According to one aspect of the invention, there is provided a semiconductor device which includes a semiconductor layer formed over an insulating layer over a semiconductor substrate, a gate electrode disposed over the semiconductor layer through a gate insulator, a sidewall insulator formed along the gate insulator and a sidewall of the gate electrode, a source/drain layer including an alloy layer whose bottom surface is in contact with the insulating layer, and an impurity-doped layer which is segregated in a self-aligned manner in an interface between the alloy layer and the semiconductor layer and has a face for junction with a channel region formed along a crystal orientation plane of the semiconductor layer.

Preferably, in the above semiconductor device, the upper surface of the source/drain layer including the alloy layer is raised above the gate insulator. The reason is that if not so, since the Si film is thin (ultra-thin SOI wafer), the width of the diffusion layer of the transistor would also be small, undesirably resulting in an increase in resistance.

Preferably, in the above semiconductor device, the crystal orientation plane is a (100) plane. The reason that a (100) plane is preferable is that silicide reaction at an raised level is desirable as mentioned above and in order to make the silicide diffusion layer as close to the channel as possible, the interface should be straight.

Preferably, in the above semiconductor device, the insulating layer is a SiO₂ film and included in an SOI substrate. The reason is that if so, the manufacturing process is easier.

Preferably, in the above semiconductor device, the alloy layer is nickel disilicide (NiSi₂). The reason is that if so, the following requirements are satisfied: selective silicidation should be effectively done, a raised diffusion layer should be formed, and both n-type and p-type impurities should be segregated to decrease the height of the Schottky barrier.

According to a second aspect of the invention, there is provided a method for manufacturing a semiconductor device which includes the steps of forming an insulating layer over a semiconductor substrate; forming a semiconductor layer over the insulating layer and forming a gate electrode over the semiconductor layer through a gate insulator; forming a sidewall insulator on the gate insulator and a sidewall of the gate electrode; implanting impurities into a whole surface of the semiconductor layer; forming a metal film on a whole surface of the semiconductor layer; forming, by inducing reaction between the metal film and the semiconductor layer by thermal processing, a source/drain layer including an alloy layer having a junction face formed along a crystal orientation plane of the semiconductor layer and, at the same time, forming an activated impurity-doped layer on an interface between the source/drain layer and the semiconductor layer by diffusing the impurities toward the semiconductor layer; and removing metal which remains unreacted at the time of formation of the alloy layer.

Preferably, in the above method, the thermal processing is performed by long-wavelength laser annealing using a laser with a wavelength of 3 μm or more at a high temperature of 800° C. or more for a ultra short duration of not more than 10 milliseconds. The reason is that by doing so, nickel disilicide (NiSi₂) can be formed in a way to satisfy the following requirements: selective silicidation should be effectively done, a raised diffusion layer should be formed, and both n-type and p-type impurities should be segregated to decrease the height of the Schottky barrier.

Preferably, in the above method, the crystal orientation plane is a (100) plane.

Preferably, in the above method, the insulating layer is a SiO₂ film and included in an SOI substrate.

Preferably, in the above method, the alloy layer is nickel disilicide (NiSi₂).

The advantageous effects achieved by the preferred embodiments of the present invention as disclosed herein are briefly summarized below.

According to the present invention, after impurity ion implantation, nickel sputtering is carried out, then annealing is carried out at a high temperature for a ultra short duration so as to stimulate electrical activation of impurities and nickel disilicidation accompanied by impurity segregation simultaneously. Since nickel disilicide has a tendency that silicide reaction easily proceeds in the face-centered cubic crystal (100) plane direction, silicide reaction effectively goes on in the vertical direction as well. For this reason, a raised diffusion layer is formed in a self-aligned manner so that the parasitic resistance of the source/drain layer is decreased. The silicide reaction width in the channel (lateral) direction is controlled by adjusting the sidewall insulator width and the annealing conditions. Since impurities are drawn to the Si side during silicide reaction, they are eventually segregated in the interface between the source/drain diffusion layer and the Si channel. A facet-free source/drain layer of nickel disilicide (fully metallic) can be formed because high-temperature annealing is carried out for a ultra short duration and the impurity segregation lowers the metal/Si Schottky barrier and decreases the interface contact resistance, leading to improvement in transistor characteristics (FIG. 18). Thus, it is possible to provide a MIS transistor which can operate at high speed due to these advantageous effects.

According to the invention, the tunnel resistance and drain terminal resistance in transistor operation can be decreased and a semiconductor device which operates at high speed can be provided.

### BRIEF DESCRIPTION OF THE DRAWINGS

FIG. 1 is a drawing which explains the background of the invention;

FIG. 2 shows the structure of a Schottky barrier MIS transistor;

FIG. 3 illustrates change in the energy band profile of a Schottky barrier MIS transistor;

FIG. 4 is a sectional view of a Schottky barrier MIS transistor as a conventional semiconductor device;

FIG. 5 is a sectional view of a Schottky barrier MIS transistor according to a previously filed patent application;

FIG. 6 is a sectional view of an essential part of a semiconductor device according to a first embodiment of the invention as an example;

FIG. 7 is a sectional view showing a manufacturing step for the semiconductor device (essential part) according to the first embodiment as an example;

FIG. 8 is a sectional view showing a manufacturing step following the step shown in FIG. 7 for the semiconductor device;

FIG. 9 is a sectional view showing a manufacturing step following the step shown in FIG. 8 for the semiconductor device;

FIG. 10 is a sectional view showing a manufacturing step following the step shown in FIG. 9 for the semiconductor device;

FIG. 11 is a sectional view showing a manufacturing step following the step shown in FIG. 10 for the semiconductor device;

FIG. 12 is a sectional view showing a manufacturing step following the step shown in FIG. 11 for the semiconductor device;

FIG. 13 is a sectional view showing a manufacturing step following the step shown in FIG. 12 for the semiconductor device;

FIG. 14 is a sectional view showing a manufacturing step following the step shown in FIG. 13 for the semiconductor device;

FIG. 15 is a sectional view showing a manufacturing step following the step shown in FIG. 14 for the semiconductor device;

FIG. 16 is a graph illustrating a laser annealing process according to a preferred embodiment of the invention;

FIG. 17 illustrates change in the energy band profile of a Schottky barrier MIS transistor according to a second embodiment of the invention;

FIG. 18 is a graph showing interface contact resistance characteristics of a semiconductor device according to a preferred embodiment of the invention; and

FIG. 19 is a graph showing Vg-ID characteristics of a semiconductor device according to a preferred embodiment of the invention.

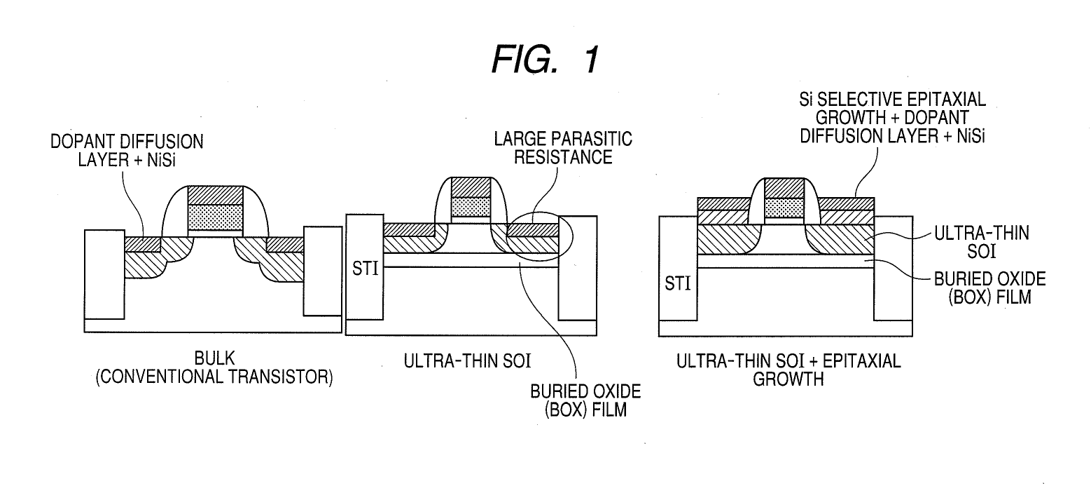

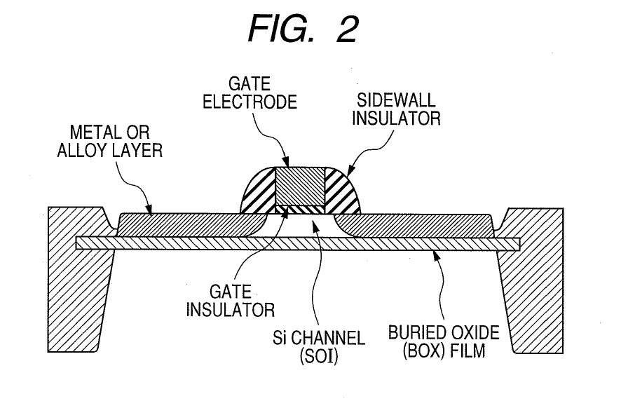

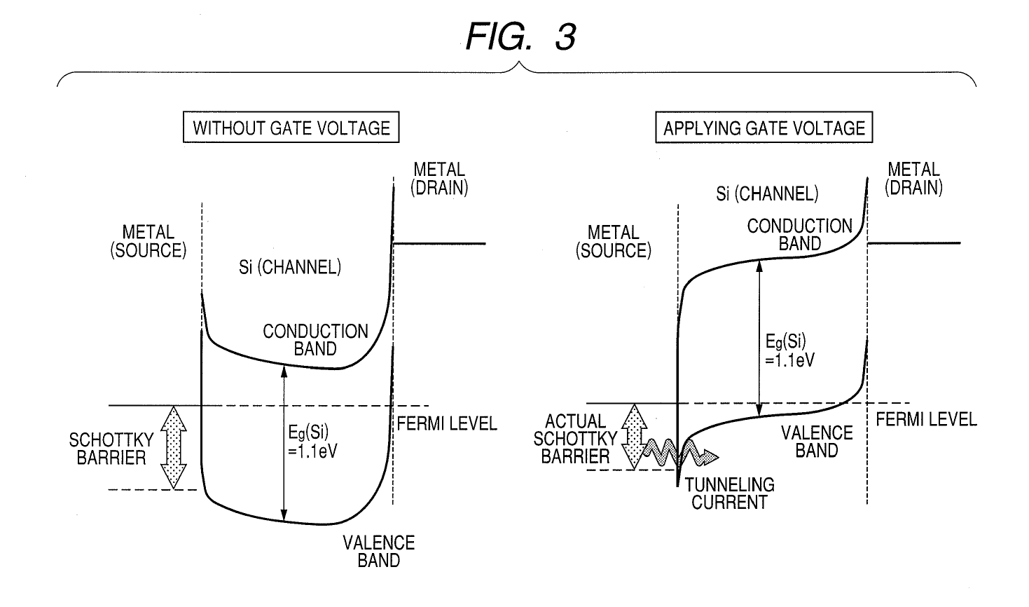

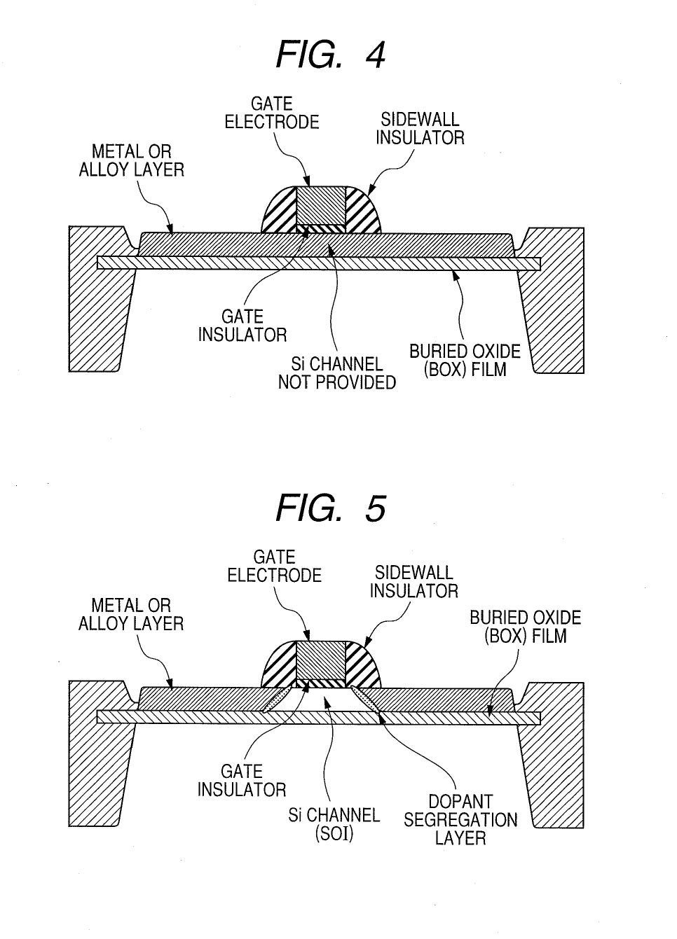

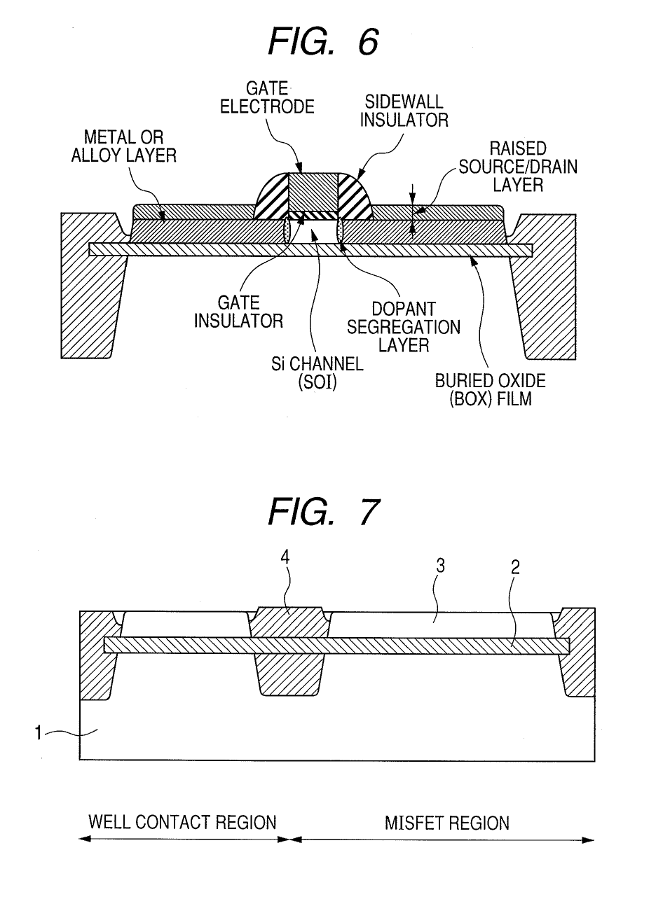

### DETAILED DESCRIPTION OF THE PREFERRED EMBODIMENTS

Next, the preferred embodiments of the present invention will be described in detail referring to the accompanying drawings. In all the drawings that illustrate the preferred embodiments, elements with like functions are designated by like reference numerals and repeated descriptions of such elements are omitted.

First Embodiment

First, a semiconductor device including a MIS transistor according to a first embodiment of the present invention will be described.

A method for manufacturing the semiconductor device according to this embodiment is explained in chronological order referring to FIGS. 7 to 15. For simple illustration, only an n-type MIS transistor will be illustrated and described while illustrations and descriptions of the other devices are omitted.

First, an SOI substrate which includes a supporting substrate 1, a buried insulating layer (BOX layer) 2, and a semiconductor layer (SOI layer) 3 as shown in FIG. 7 is prepared. The supporting substrate 1 is made of p-type monocrystalline silicon having a plane orientation of (100) and a resistivity of about 5 Ωcm. The SOI layer 3 is made of p-type monocrystalline silicon having a plane orientation of (100) and a crystal orientation of <110> in the direction parallel to an orientation flat or notch, and a thickness of 30 nm. The BOX layer 2 is made of oxide silicon with a thickness of 10 nm. A device isolation trench 4 with a depth of about 300 nm which reaches the supporting substrate 1 from the surface of the SOI layer 3 is made using a known STI (shallow trench isolation) technique.

Then, as shown in FIG. 8, in order to enable contact with a well in the FDSOI device formation region of the MIS transistor, the SOI layer 3 and BOX layer 2 in the contact region are removed by dry etching and wet etching so that the surface of the supporting substrate 1 is partially exposed. Since the exposed surface of the supporting substrate 1 is the interface for bonding between the BOX layer 2 and supporting substrate 1, the surface layer is partially removed by sacrificial oxidation as necessary.

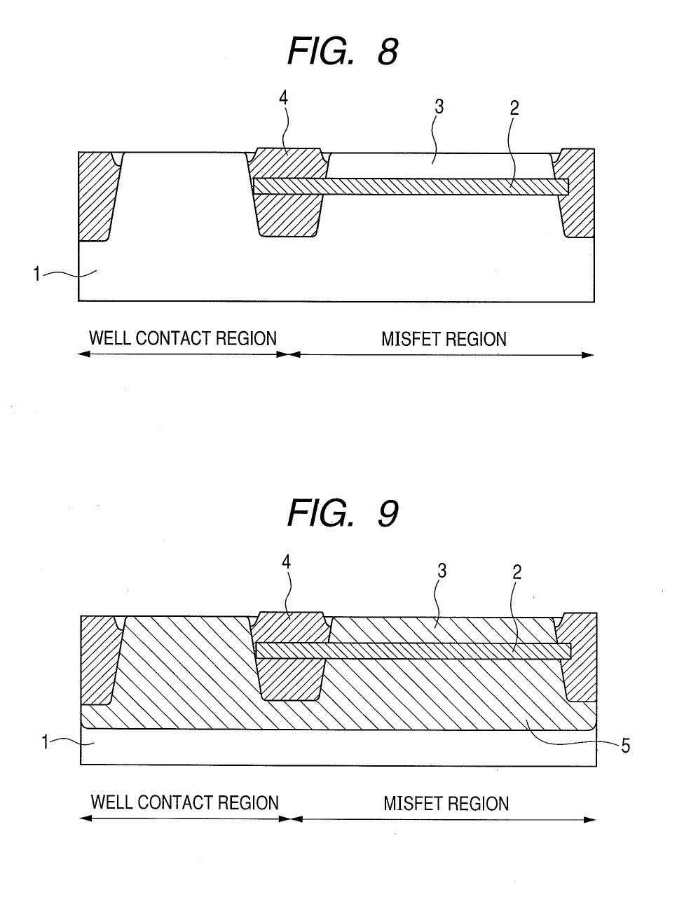

Then, as shown in FIG. 9, a p-type well 5 is formed in the supporting substrate 1 by impurity ion implantation and rapid thermal processing for activation of impurities. An adjustment is made so that the peak impurity concentration is 10¹⁸/cm³ or so and its peak depth position is deeper than the BOX layer 2.

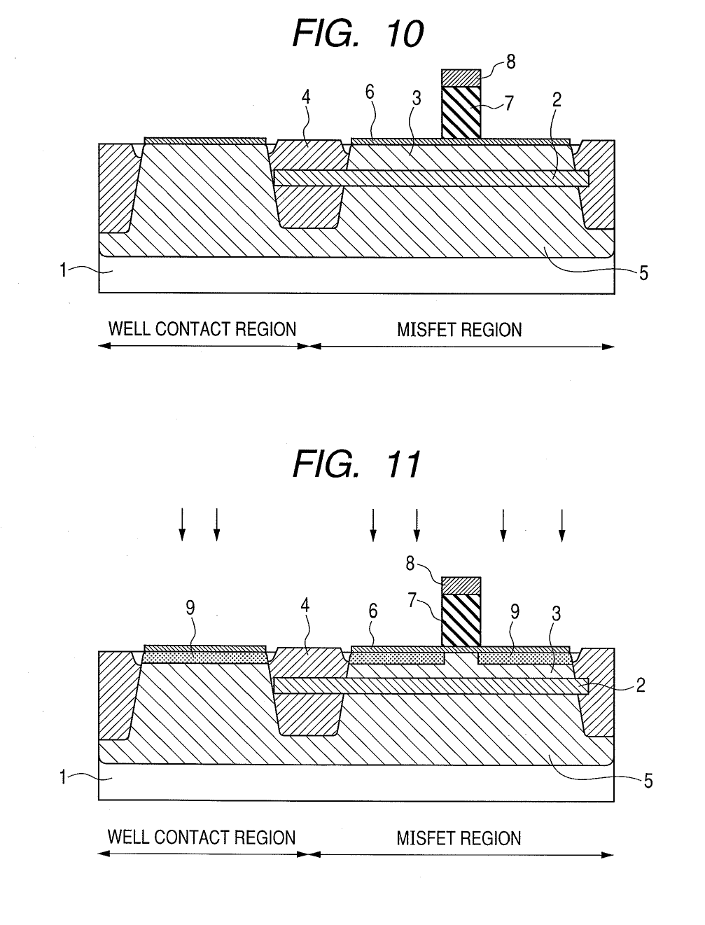

Then, as shown in FIG. 10, after formation of a gate insulator 6 with a thickness of about 2 nm by surface thermal oxidation, a polycrystalline silicon film 7 is deposited on the gate insulator 6 by a CVD process and an oxide silicon film 8 for gate protection is deposited on the polycrystalline silicon film 7 by a CVD process. Then, a gate electrode for the n-type MIS transistor is completed by dry-etching these films.

Then, as shown in FIG. 11, an n- type semiconductor region 9 is formed by impurity ion implantation into the SOI layer 3 on both sides of the gate electrode 8 and into the contact region of the supporting substrate 1 (p-type well 5).

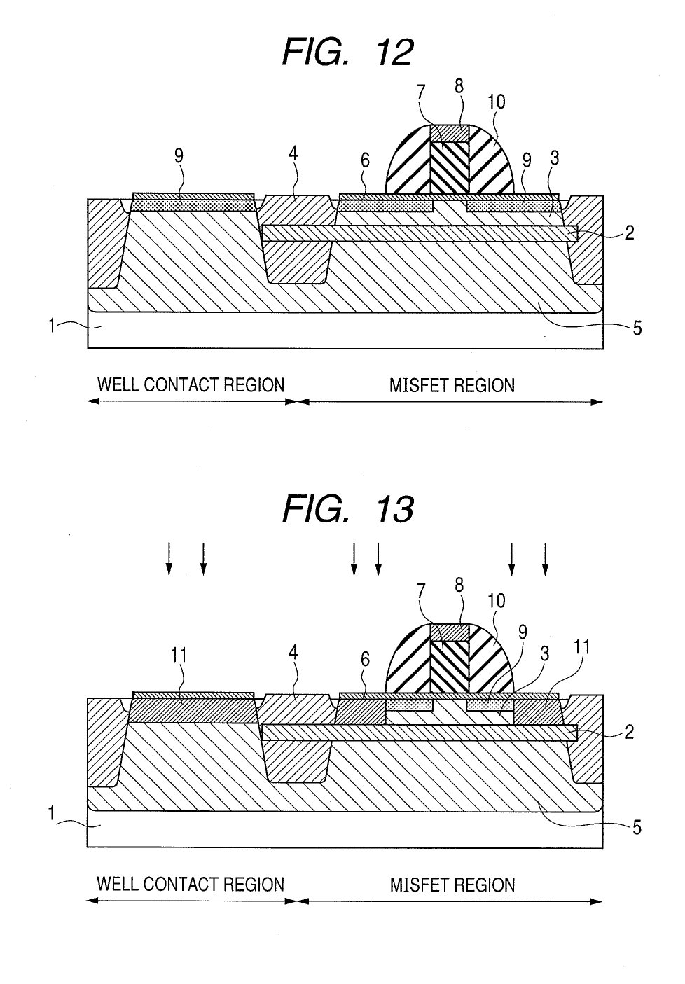

Then, as shown in FIG. 12, a sidewall spacer 10 is formed on the sidewall of the gate electrode by dry-etching the nitride silicon film deposited by a CVD process. The width of the sidewall spacer is, for example, about 20 nm.

Then, as shown in FIG. 13, an n+semiconductor region 11 is formed in the SOI layer 3 on both sides of the sidewall spacer 10 and in the contact region of the supporting substrate 1 (p-type well 5) by impurity ion implantation.

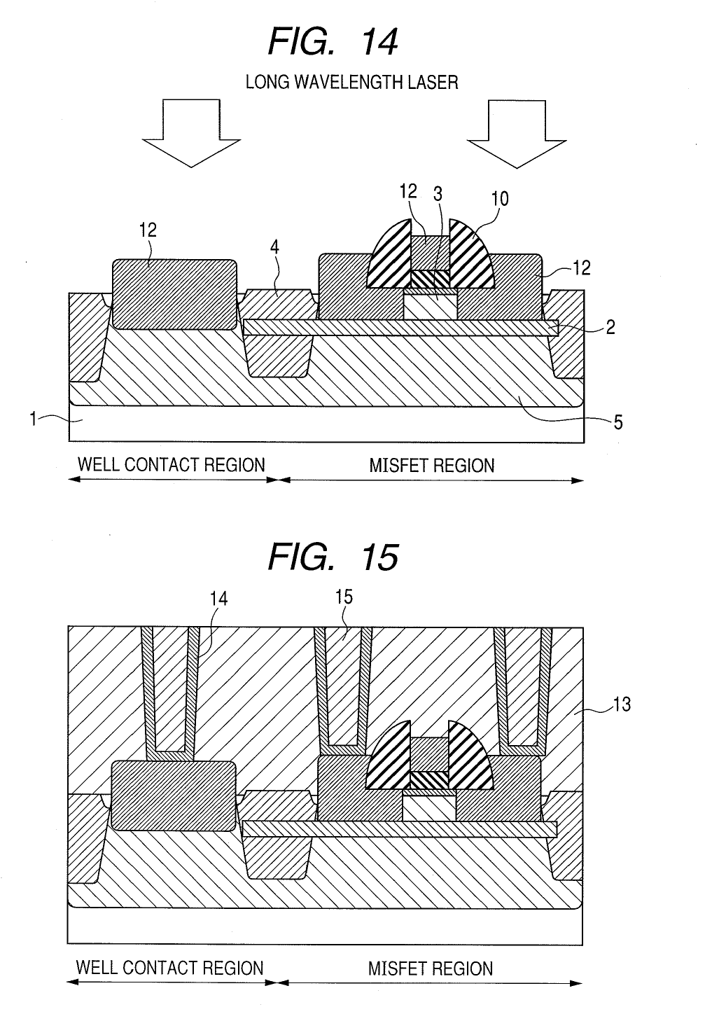

Then, after removal of the oxide silicon film 8 for gate protection by a known cleaning technique, nickel is deposited by a known sputtering technique. The sputtered film thickness should be, for example, 20 nm or so. Then, as shown in FIG. 14, in order to simultaneously perform the process of increasing the electrical activity of impurities implanted into the n- semiconductor region 9 and n+ semiconductor region 11 and the process of forming a nickel disilicide layer 12 accompanied by impurity segregation, long-wavelength laser annealing is carried out at high temperature for a ultra short duration. For example, the annealing conditions are 1200° C. and 800 μs. Since nickel disilicide has a tendency that silicide reaction easily proceeds in the face-centered cubic (100) plane direction, silicide reaction effectively proceeds in the vertical direction as well. For this reason, an raised diffusion layer is formed in a self-aligned manner so that the parasitic resistance of the source/drain layer is decreased. The silicide reaction width in the channel direction (lateral direction) is controlled by adjusting the sidewall insulator width and the annealing conditions. Since impurities are drawn to the Si side during silicide reaction, they are eventually segregated in the interface between the source/drain diffusion layer and Si channel. A facet-free source/drain layer of nickel disilicide (fully metallic) can be formed because high-temperature annealing is carried out for a ultra short duration to form it.

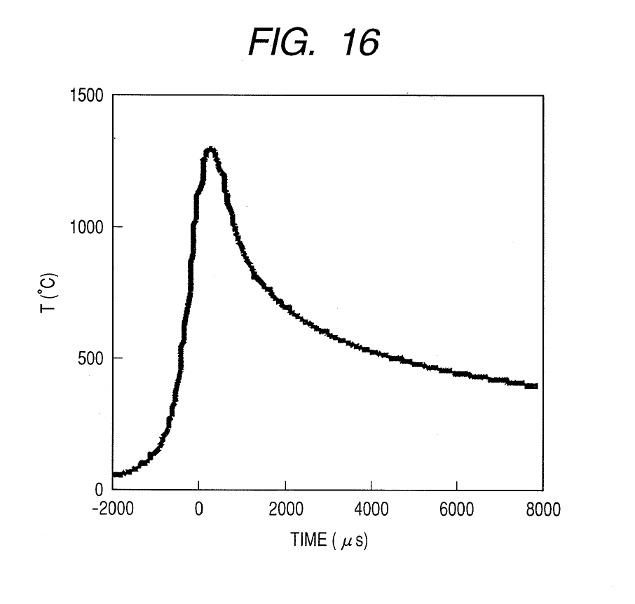

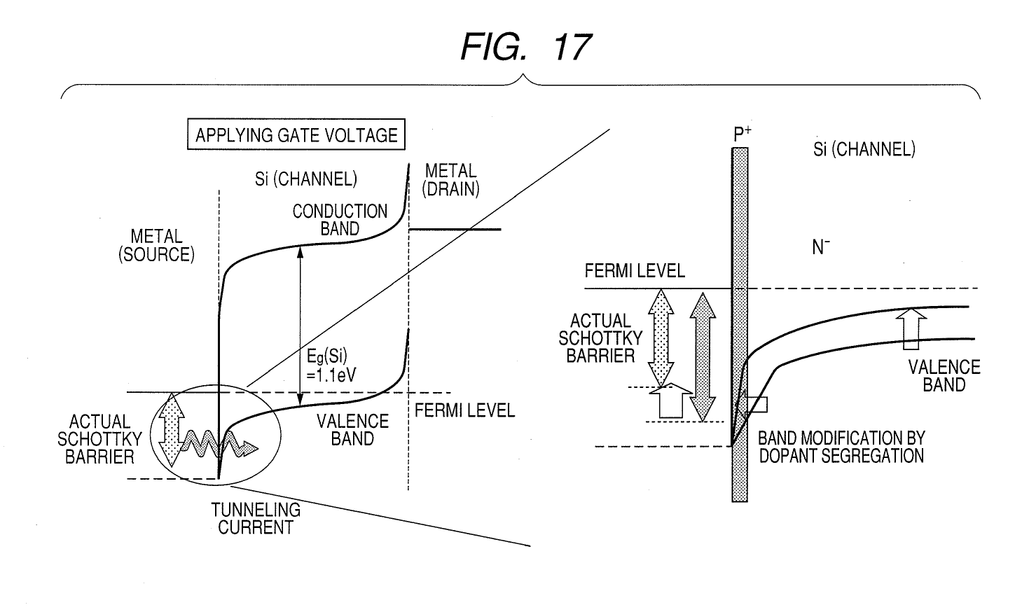

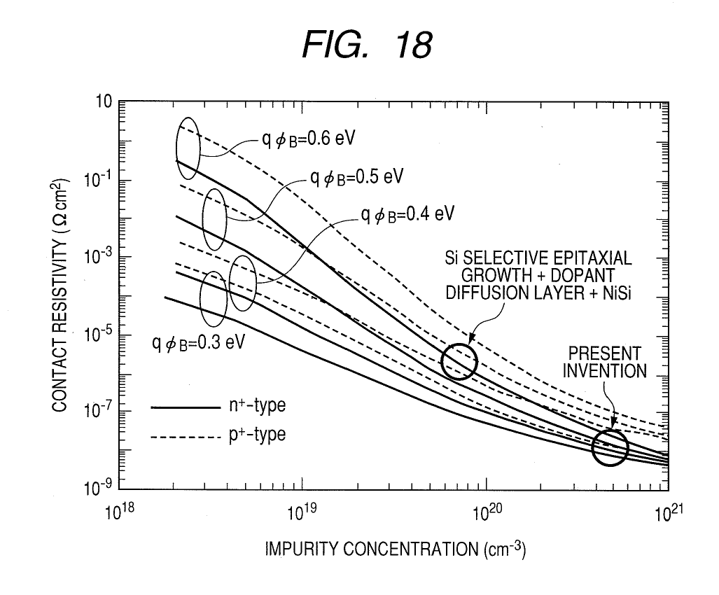

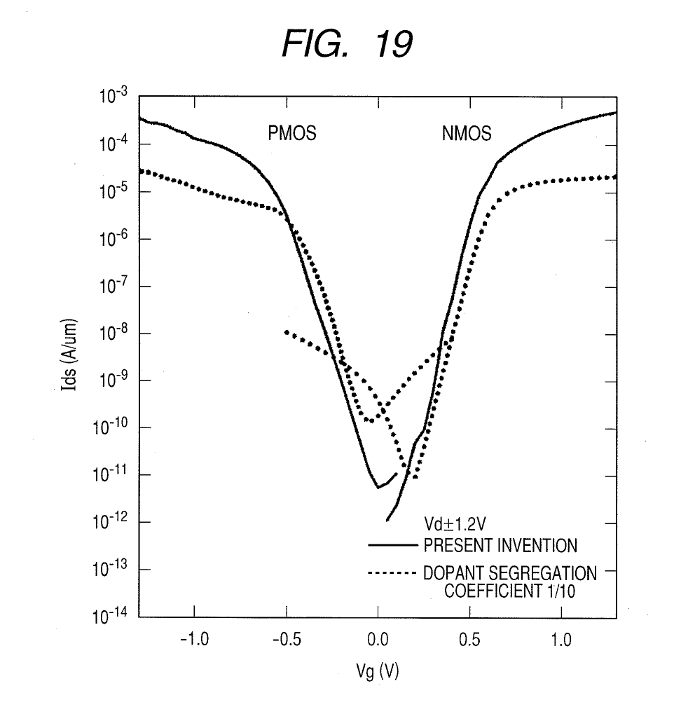

In this embodiment, the annealing process uses a long-wavelength laser, where the wavelength of laser light employed is preferably 3 μm or more, more preferably 5 μm or more, and most preferably 8 μm or more. For example, annealing can be performed by scanning a wafer using a CO₂ gas laser (wavelength 10.6 μm). The peak temperature and annealing time are determined as shown in FIG. 16 according to laser beam width, laser light intensity, and scan time. The annealing target area can be heated to a desired temperature by irradiating the main surface of the wafer by a long-wavelength laser. In this embodiment, since a long-wavelength laser is used for annealing, it is possible to raise the annealing temperature to a higher temperature more quickly than when a lamp annealing process for rapid thermal annealing (RTA) is employed.

Then, as shown in FIG. 15, after an interlayer insulating film 13, an oxide silicon film, is deposited by a CVD process, the interlayer insulating film 13 is dry-etched to form a contact hole 14 which exposes the nickel disilicide surface. Then, a plug 15 (W film) is made inside the contact hole 14 and subsequently an interconnect (Al alloy film) is formed over the interlayer insulating film 13. The subsequent interconnect formation process is neither illustrated nor described here because it is the same as a known interconnect formation process.

Second Embodiment

In the second embodiment, a known photolithographic technique is used to form a p-channel MISFET and complete a CMISFET where the polarities (n type, p type) are reversed in all ion implantation steps. FIG. 17 illustrates the effect of an dopant segregation layer in a semiconductor device according to the second embodiment of the present invention. A p+/n−abrupt junction is formed by a high-concentration dopant segregation layer; the depletion layer is narrow; and hole injection by tunneling current at the valence band edge increases. In other words, this suggests that the Schottky barrier lowers.

In this embodiment, by controlling the polycrystalline silicon film thickness, the polycrystalline silicon film can also be fully silicidized to form a full silicide gate electrode. Also a gate electrode may be formed from a metal material such as TiN film using a known gate damascene technique or similar technique. It is needless to say that any other metal may be used to form a gate electrode.

In this embodiment, any other metals which include Pt and Er may be used as sputtering materials. If one of known sputtering materials such as titanium silicide (TiSi₂), cobalt silicide (CoSi₂), and nickel monosilicide (NiSi) is used and the same effect as achieved by the present invention can be obtained by using an improved sputtering technique, any of these alloys may be used to form a gate electrode.

In the above description of this embodiment, it has been assumed that the buried insulating layer (BOX layer) 2 and semiconductor layer (SOI layer) 3 of the FDSOI MIS transistor are thin. However, the thicknesses of these films are not limited thereto and may have any desired thickness.

The supporting substrate 1 may be a semiconductor substrate of Si, Ge, SiGe, GaAs, InP, GaP, GaN, or SiC, or an insulating substrate of glass, sapphire, or ceramic. The material of the semiconductor layer as a substitute for the SOI layer 3 may be Ge, SiGe, SiC, SiSn, PbS, GaAs, InP, GaP, GaN, ZnSe or the like and the insulating layer as a substitute for the BOX layer 2 may be an insulating layer or buried insulating film of SiON or Si₃N₄. The SOI substrate may be a SIMOX substrate, laminated substrate or laser-annealed substrate. Also, a polycrystalline semiconductor layer or amorphous semiconductor layer may be used instead of the SOI layer 3.

The material of the gate insulator 6 is typically SiO₂ but it may be one of the following dielectric materials: HfO₂, HfON, HfAlO, HfAlON, HfSiO, HfSiON, ZrO₂, ZrON, ZrAlO, ZrAlON, ZrSiO, ZrSiON, and Ta₂O₅.

The invention made by the present inventors has been so far explained in reference to the preferred embodiments thereof. However, the invention is not limited thereto and it is obvious that these details may be modified in various ways without departing from the spirit and scope of the invention.

The present invention can be widely used in the semiconductor device manufacturing industry.

What is claimed is:

1. A semiconductor device comprising:
a semiconductor layer formed over an insulating layer over a semiconductor substrate;
a gate electrode disposed over the semiconductor layer through a gate insulator;
a sidewall insulator formed along the gate insulating film and a sidewall of the gate electrode;
a source/drain layer including an alloy layer whose bottom surface is in contact with the insulating layer; and
an impurity-doped layer which is segregated in a self-aligned manner in an interface between the alloy layer and the semiconductor layer and has a face for, junction with a channel region formed along a crystal orientation plane of the semiconductor layer.

2. The semiconductor device according to claim 1, wherein the source/drain layer including the alloy layer has an upper surface is raised above the gate insulator.

3. The semiconductor device according to claim 1, wherein the crystal orientation plane is a (100) plane.

4. The semiconductor device according to claim 1, wherein the insulating layer is a SiO₂ film and included in an SOI substrate.

5. The semiconductor device according to claim 1, wherein the alloy layer is nickel disilicide (NiSi₂).

6. A method for manufacturing a semiconductor device comprising:
forming an insulating layer over a semiconductor substrate;
forming a semiconductor layer over the insulating layer and forming a gate electrode over the semiconductor layer through a gate insulator;
forming a sidewall insulator on the gate insulator and a sidewall of the gate electrode;
implanting impurities into a whole surface of the semiconductor layer;
forming a metal film on a whole surface of the semiconductor layer;
forming, by inducing reaction between the metal film and the semiconductor layer by thermal processing, a source/drain layer comprising an alloy layer having a junction face formed along a crystal orientation plane of the semiconductor layer and, at the same time, forming an activated impurity-doped layer on an interface between the source/drain layer and the semiconductor layer by diffusing the impurities toward the semiconductor layer; and
removing metal which remains unreacted at the time of formation of the alloy layer.

7. The method for manufacturing a semiconductor device according to claim 6, wherein the thermal processing is performed by long-wavelength laser annealing using a laser with a wavelength of 3 μm or more at a high temperature of 800° C. or more for a ultra short duration of not more than 10 milliseconds.

8. The method for manufacturing a semiconductor device according to claim 6, wherein the crystal orientation plane is a (100) plane.

9. The method for manufacturing a semiconductor device according to claim 6, wherein the insulating layer is a SiO₂ film and included in an SOI substrate.

10. The method for manufacturing a semiconductor device according to claim 6, wherein the alloy layer is nickel disilicide (NiSi₂).
